(19) United States
(12) Patent Application Publication
(10) Pub. No.: US 2025/0151551 A1
(43) Pub. Date: May 8, 2025

(54) DISPLAY APPARATUS

(71) Applicant: LG Display Co., Ltd., Seoul (KR)

(72) Inventors: Jeongjae BAN, Paju-si (KR); Wonhee LEE, Paju-si (KR)

(21) Appl. No.: 18/830,375

(22) Filed: Sep. 10, 2024

(30) Foreign Application Priority Data
Nov. 7, 2023 (KR) 10-2023-0152685

(51) Int. Cl. H10K 59/131

(52) U.S. Cl. CPC H10K 59/131

(57) ABSTRACT

An aspect of the present disclosure is directed to providing a display apparatus which can prevent corrosion of a wiring. The display apparatus includes a substrate including a display area and a non-display area around the display area. The display apparatus includes pixels in the display area. The display apparatus includes a wiring electrically connected to pixels and extending from the display area to the non-display area. The display apparatus includes a passivation layer covering an end of the wiring in the non-display area. The display apparatus includes an insulation layer on the passivation layer in a thickness direction of the substrate and overlapping the end of the wiring. The passivation layer and the insulation layer provided in the thickness direction of the substrate overlap each other at an end of the wiring.

### CROSS-REFERENCE TO RELATED APPLICATIONS

This application claims the benefit of the Korean Patent Application No. 10-2023-0152685 filed on Nov. 7, 2023, which is hereby incorporated by reference as if fully set forth herein.

### BACKGROUND

### Technical Field

The present disclosure relates to a display apparatus.

### Description of the Related Art

With the development of technology, a display apparatus is being applied to various electronic devices such as TVs, mobile phones, laptops, and tablets, and transportation means. A display apparatus is becoming thinner, lighter, and lower power consumption, and research for this purpose is continuing.

The display apparatus is composed of various layers, and accordingly, the display apparatus can have several problems. For example, because a display apparatus is formed of various layers, a step can occur. Therefore, problems such as visibility and corrosion of a wiring can occur.

### BRIEF SUMMARY

Accordingly, the present disclosure is directed to providing a display apparatus that substantially obviates one or more problems due to limitations and disadvantages of the related art.

An aspect of the present disclosure is directed to providing a display apparatus which can prevent corrosion of a wiring.

Another aspect of the present disclosure is directed to providing a display apparatus having a structure in which the pressure applied to a wiring can be reduced.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a display apparatus comprising a substrate including a display area and a non-display area around the display area, pixels in the display area, a wiring electrically connected to pixels and extending from the display area to the non-display area, a passivation layer covering an end of the wiring in the non-display area, and an insulation layer on the passivation layer in a thickness direction of the substrate and overlapping the end of the wiring.

In the display apparatus according to an embodiment of the present disclosure, the passivation layer and the insulation layer provided in the thickness direction of the substrate can overlap each other at an end of the wiring.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display apparatus according to embodiments of the present disclosure;

FIG. 2 is a cross-sectional view of a display area according to embodiments of the present disclosure;

FIG. 3 is a cross-sectional view of a display apparatus according to an embodiment of the present disclosure;

FIG. 4 is a cross-sectional view of a display apparatus according to another embodiment of the present disclosure;

FIG. 5 is a cross-sectional view of a display apparatus according to another embodiment of the present disclosure; and

FIG. 6 is a cross-sectional view of an element of a display apparatus according to embodiments of the present disclosure.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a dimension (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct (ly)” is used.

In describing a time relationship, for example, when the temporal order is described as, for example, “after,” “subsequent,” “next,” and “before,” a case that is not continuous can be included unless a more limiting term, such as “just,” “immediate (ly),” or “direct (ly)” is used.

It will be understood that, although the terms “first,” “second,” etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc., can be used. These terms are intended to identify the corresponding elements from the other elements, and basis, order, or number of the corresponding elements should not be limited by these terms. The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings.

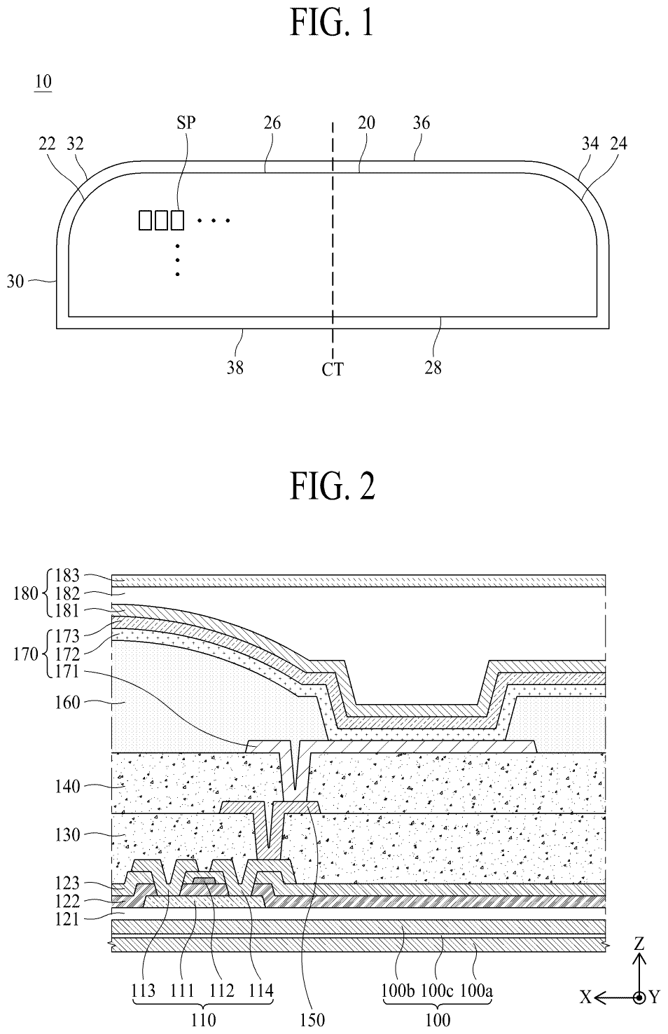

FIG. 1 is a plan view of a display apparatus according to embodiments of the present disclosure.

Referring to FIG. 1, a display apparatus 10 can include a display area 20 for displaying an image and a non-display area 30 around the display area 20. The display area 20 can include subpixels SP. A subpixel SP can be electrically connected to a thin film transistor included in the display apparatus 10. The subpixels SP can include a red subpixel, a green subpixel, and a blue subpixel, but is not limited thereto.

The display area 20 can be a light emitting area or an active area. The display area 20 can include a first surface 22, a second surface 24, a third surface 26, and a fourth surface 28.

The first surface 22 and the second surface 24 can include one surface of the display apparatus 10 and the other surface provided on an opposite side of the one surface. For example, the first surface 22 and the second surface 24 can be symmetrical with respect to a center CT of the display apparatus 10. The first surface 22 and the second surface 24 can be bilaterally symmetrical, but are not limited thereto.

The first surface 22 and the second surface 24 can include curved surfaces. For example, the first surface 220 and the second surface 24 can have one or more curvatures.

The third surface 26 can include an upper surface of the display apparatus 10. The third surface 26 can be provided between the first surface 22 and the second surface 24. The third surface 26 can include a curved surface. For example, the third surface 26 can have one or more curvatures.

The fourth surface 28 can be provided at an opposite side of the third surface 26. The fourth surface 28 can be provided between the first surface 22 and the second surface 24. The fourth surface 28 may not include a curved surface. For example, the fourth surface 28 can be perpendicular to each of the first surface 22 and the second surface 24, but is not limited thereto.

The non-display area 30 can include a fifth surface 32, a sixth surface 34, a seventh surface 36, and an eighth surface 38.

The fifth surface 32, the sixth surface 34, the seventh surface 36, and the eighth surface 38 can be provided to correspond to the first surface 22, the second surface 24, the third surface 26, and the fourth surface 28, respectively.

The fourth surface 28 or the eighth surface 38 can include a circuit board. The circuit board can include an integrated chip (IC) performing various functions and can be electrically connected to the display apparatus 10. For example, the circuit board can be electrically connected to the subpixel SP so that the display apparatus 10 can display an image.

FIG. 2 is a cross-sectional view of a display area according to embodiments of the present disclosure.

Referring to FIG. 2, a display apparatus according to embodiments of the present disclosure can include a substrate 100, a thin film transistor 110, a light emitting unit 170, and an encapsulation unit 180.

The substrate 100 can include one or more plastic materials. For example, the substrate 100 can include a first substrate 100a and a second substrate 100b on the first substrate 100a. Each of the first substrate 100a and the second substrate 100b can include a plastic material such as polyimide. However, the present disclosure is not limited thereto.

The substrate 100 can include an intermediate layer 100c interposed between the first substrate 100a and the second substrate 100b. The intermediate layer 100c can block moisture penetration from an outside through the substrate 100. The intermediate layer 100c can electrically insulate the substrate 100. For example, the intermediate layer 100c can include an electrical insulation material and an inorganic material, but is not limited thereto.

The thin film transistor 110 can be disposed on the substrate 100. The thin film transistor 110 can include a semiconductor layer 111, a gate electrode 112, a source electrode 113, and a drain electrode 114.

A buffer layer 121 can be formed between the substrate 100 and the thin film transistor 110. The buffer layer 121 can prevent a material included in the substrate 100 from being diffused into the thin film transistor 110 during a high-temperature process in a manufacturing process of the thin film transistor 110 or prevent external moisture or humidity from penetrating into the light emitting layer. The buffer layer 121 can be omitted depending on the type, material, or the like of the substrate 100, but is not limited thereto.

The semiconductor layer 111 can be formed on the buffer layer 121.

The semiconductor layer 111 can include a source area, a drain area, and a channel area between the source area and the drain area.

The semiconductor layer 111 can include a metal oxide semiconductor such as an indium-gallium-Zinc oxide (IGZO), or a silicon-based semiconductor material such as amorphous silicon or polycrystalline silicon, but is not limited thereto.

A first insulation layer 122 can be formed on the semiconductor layer 111. The first insulation layer 122 can cover the semiconductor layer 111. The first insulation layer 122 can be formed in an island shape only on the channel area of the semiconductor layer 111 or can be formed to cover the entire surface of the substrate 100 including the semiconductor layer 111 or the buffer layer 121. The first insulation layer 122 can be formed as a single layer of an inorganic material including silicon nitride (SiNx) or silicon oxide (SiOx), or multiple layers including the same, but is not limited thereto.

The gate electrode 112 can be formed on the first insulation layer 122. The gate electrode 112 can be formed on the first insulation layer 122 to overlap the channel area of the semiconductor layer 111. The gate electrode 112 can be formed in a single layer or multiple layers including molybdenum (Mo), copper (Cu), titanium (Ti), aluminum (Al), chromium (Cr), gold (Au), nickel (Ni), neodymium (Nd), or a compound thereof. The gate electrode 112 can be formed together with a gate line.

A second insulation layer 123 can be formed on the gate electrode 112.

The second insulation layer 123 can cover the gate electrode 112. The second insulation layer 123 can be formed in a single layer of an inorganic material including silicon nitride (SiNx) or silicon oxide (SiOx), or multiple layers thereof, but is not limited thereto. For example, the second insulation layer 123 can be formed of an organic material.

The source electrode 113 and the drain electrode 114 can be formed on the second insulation layer 123. The source electrode 113 and the drain electrode 114 can be electrically connected to the semiconductor layer 111 through contact holes formed in the first insulation layer 122 and the second insulation layer 123. The source electrode 113 and the drain electrode 114 can be formed of a metallic material. For example, the source electrode 113 and the drain electrode 114 can be a single layer or multiple layers formed of at least one of molybdenum (Mo), aluminum (Al), chromium (Cr), gold (Au), titanium (Ti), nickel (Ni), neodymium (Nd), and copper (Cu), or an alloy thereof, but are not limited thereto.

The source electrode 113 and the drain electrode 114 can be formed together with a data line. For example, the data line can be formed of the same material as the source electrode 113 and the drain electrode 114, and can be formed on the same layer, but is not limited thereto.

A first passivation layer 130 can be formed on the source electrode 113 and the drain electrode 114.

The first passivation layer 130 can planarize an upper end of the thin film transistor 110 and protect the thin film transistor 110. The first passivation layer 130 can be formed of an organic material. For example, the first passivation layer 130 can be formed of an organic material including an acrylic resin, an epoxy resin, a phenolic resin, a polyamide resin, or a polyimide resin, but is not limited thereto.

A second passivation layer 140 can be formed on the first passivation layer 130. The second passivation layer 140 can be formed of the same material as the first passivation layer 130, but is not limited thereto.

A connection electrode 150 can be formed between the first passivation layer 130 and the second passivation layer 140.

The connection electrode 150 can electrically connect the thin film transistor 110 and the light emitting unit. The connection electrode 150 can be formed of the same material as the source electrode 113 and the drain electrode 114, but is not limited thereto.

A bank 160 and the light emitting unit 170 can be formed on the second passivation layer 140.

The light emitting unit 170 can include a first electrode 171, a light emitting layer 172, and a second electrode 173.

The first electrode 171 can be formed on the second passivation layer 140. The first electrode 171 can be electrically connected to the thin film transistor 110 through a contact hole formed in the second passivation layer 140.

The first electrode 171 can be an anode electrode. For example, the first electrode 171 can be a reflective electrode which reflects light.

The light emitting layer 172 can be formed on the first electrode 171. The light emitting layer 172 can include one or more light emitting structures stacked on the first electrode 171 in the order or in the reverse order of a hole transport layer and an electron transport layer. A detailed light emitting structure of the light emitting layer 172 will be described later.

The second electrode 173 can be formed on the light emitting layer 172. The second electrode 173 can be a cathode electrode. For example, the second electrode 173 can be a transparent electrode which transmits light.

The bank 160 can be formed to expose the first electrode 171. The bank 160 can define an opening portion (or a light emitting area) of the subpixel and can be disposed to cover an edge portion of the first electrode 171. The subpixels can include a red light emitting area, a green light emitting area, and a blue light emitting area. For example, the subpixel can be referred to as a pixel, but is not limited thereto.

The bank 160 can be formed of an organic material such as photo-acrylic, can be a translucent material, but is not limited thereto. For example, the bank 160 can be formed of an opaque material to prevent light interference between subpixels.

The encapsulation unit 180 can be formed on the bank 160 or the light emitting unit 170. The encapsulation unit 180 can include one or more insulation layers. For example, the encapsulation unit 180 can include a fourth insulation layer 181, a fifth insulation layer 182, and a sixth insulation layer 183. The encapsulation unit 180 can include one or more inorganic material layers and one or more organic material layers. For example, the fourth insulation layer 181 and the sixth insulation layer 183 can include an inorganic material, and the fifth insulation layer 182 can include an organic material.

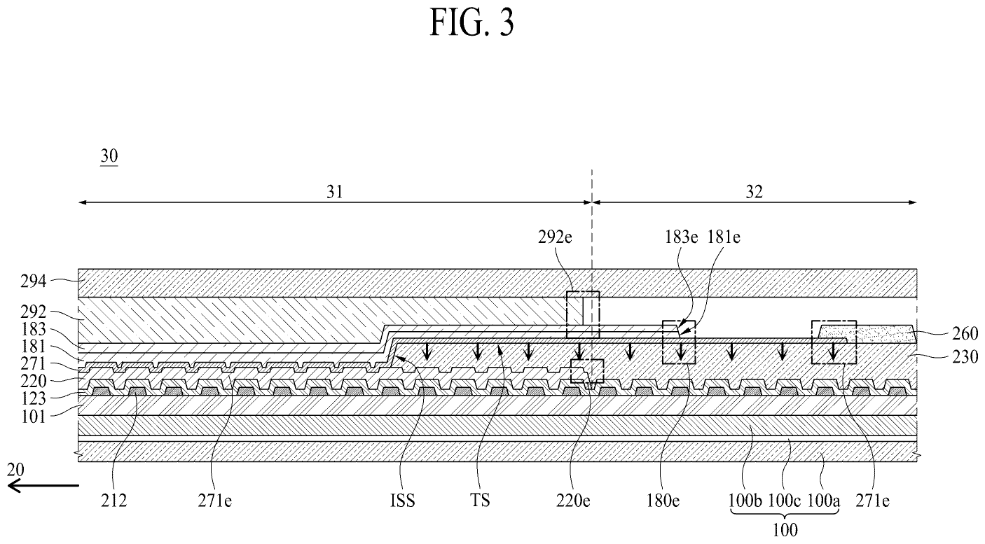

FIG. 3 is a cross-sectional view of a display apparatus according to an embodiment of the present disclosure.

Some of the configurations illustrated in FIG. 3 are formed by extending the configurations of the display area 20 illustrated in FIG. 2 to the non-display area 30, and can be substantially the same. Referring to FIGS. 1 to 3, the substrate 100 can be formed over the display area 20 and the non-display area 30 around the display area 20. Hereinafter, descriptions substantially the same as that of FIG. 2 will be given the same reference numerals, redundant descriptions thereof will be omitted, and details different from that of FIG. 2 will be described.

Referring to FIGS. 1 to 3, a first wiring 212 can be formed on the substrate 100. The first wiring 212 can be formed on the same layer as the gate electrode 112 in the display area 20. The first wiring 212 can be a gate line, but is not limited thereto.

The second wiring 220 can be formed on the first wiring 212. The second wiring 220 can extend to the non-display area 30 through the display area 20. The second wiring 220 can include an end 220e of the second wiring. The end 220e of the second wiring can be formed in the non-display area 30.

The second wiring 220 can be electrically connected to the subpixel SP of the display area 20. For example, the second wiring 220 can be electrically connected to a plurality of pixels.

The second wiring 220 can be formed on the same layer as the source electrode 113 and the drain electrode 114 in the display area 20.

A third passivation layer 230 can be formed on the second wiring 220. The third passivation layer 230 can be formed on the same layer as the first passivation layer 130 or the second passivation layer 140 and can be formed of the same material as the first passivation layer 130 or the second passivation layer 140, but is not limited thereto.

The third passivation layer 230 can overlap a portion of the second wiring 220 in a thickness direction of the substrate 100. For example, the end 220e of the second wiring can overlap the third passivation layer 230 in a thickness direction of the substrate 100. In addition, the end 220e of the second wiring can overlap the third passivation layer 230 from a plan view. Further, the end 220e of the second wiring 220 is located at an area where both the passivation layer 230 and the insulation layer 181 or 181 overlap with each other from a plan view.

A metal layer 271 can be formed on the second wiring 220. The metal layer 271 can be formed on the same layer as the first electrode 171 of the display area 20. The metal layer 271 can include an end 271e of the metal layer. A portion of the metal layer 271 can overlap the second wiring 220 in a thickness direction of the substrate 100. For example, the end 271e of the metal layer can overlap the second wiring 220 in the thickness direction of the substrate 100. In addition, the end 271e of the metal layer can overlap the second wiring 220 from a plan view.

The metal layer 271 can be formed to be spaced apart from the second wiring 220 and the second insulation layer 123 by the third passivation layer 230.

For example, a portion of the metal layer 271 can contact the second wiring 220, and the rest of the metal layer 271 can contact the third passivation layer 230, but is not limited thereto. Referring to FIG. 3, a portion of the metal layer 271 contacts the second wiring 220, and the rest of the portion of the metal layer 271 extends to an inclined side surface ISS of the third passivation layer 230 and further extends over a top surface TS of the third passivation layer 230.

The fourth insulation layer 181 can be formed on the metal layer 271. The fourth insulation layer 181 can extend from the display area 20 and be formed over the non-display area 30.

The sixth insulation layer 183 can be formed on the fourth insulation layer 181. The sixth insulation layer 183 can extend from the display area 20 and be formed over the non-display area 30. The fourth insulation layer 181 and the sixth insulation layer 183 can include an end 180e of the fourth insulation layer 181 and the sixth insulation layer 183. The end 181e of the fourth insulation layer 181 and the end 183e of the sixth insulation layer 183 can overlap or completely overlap, but the present disclosure is not limited thereto. The end 181e of the fourth insulation layer 181 and the end 183e of the sixth insulation layer 183 can be collectively referred to as the end 181e of the fourth insulation layer 181 and the sixth insulation layer 183.

The end 220e of the second wiring can overlap the fourth insulation layer 181 and the sixth insulation layer 183 in a thickness direction of the substrate 100. For example, the third passivation layer 230, the fourth insulation layer 181, and the sixth insulation layer 183 can overlap each other at the end 220e of the second wiring in the thickness direction of the substrate 100. Namely, the third passivation layer 230, the fourth insulation layer 181, and the sixth insulation layer 183 can overlap each other at the end 220e of the second wiring from a plan view.

A functional film 292 can be formed on the sixth insulation layer 183. The functional film 292 can have a shape in which one or more functional layers are stacked. For example, the functional film 292 can include an antireflection layer such as a polarizing film capable of improving outdoor visibility and contrast ratio with respect to an image displayed by the display apparatus 10 by preventing reflection of external light. For example, the functional film 292 can further include a barrier layer for preventing penetration of moisture or oxygen from the outside. The barrier layer can be formed of a material having low moisture permeability, such as a polymer material. For example, the functional film 292 can include an antireflection film, a polarizing film, a barrier film, a touch film, or a light control film, but embodiments of the present disclosure are not limited thereto.

The functional film 292 can include an end 292e of the functional film. The end 292e of the functional film can overlap the fourth insulation layer 181 and the sixth insulation layer 183 from a plan view.

The front member 294 can be formed on the functional film 292. The front member 294 can protect the display apparatus 10 from external impact and transmit light emitted from the display area 20. The front member 294 can be a cover glass, a window cover, a cover window, or the like, and embodiments of the present disclosure are not limited thereto.

The front member 294 can be formed to cover the front surface of the display apparatus 10.

The front member 294 can be formed of a material capable of stretching and/or contracting. For example, the front member 294 can be formed of a transparent plastic material, a glass material, or a tempered glass material, but is not limited thereto.

When the functional film 292 and/or the front member 294 are attached to the components on the substrate 100, an adhesive member having an adhesive force can be formed under the functional film 292 and/or the front member 294. For example, in order to form the functional film 292 and/or the front member 294 on the substrate 100 in the display apparatus 10, the substrate 100 can be bonded to the functional film 292 and/or the front member 294 in the thickness direction of the substrate 100.

A metal layer 271 can be formed on the second wiring 220.

The metal layer 271 can include an end 271e of the metal layer.

The fourth insulation layer 181 and the sixth insulation layer 183 can be formed on the metal layer 271. The fourth insulation layer 181 and the sixth insulation layer 183 can include end 180e of the fourth insulation layer and the sixth insulation layer.

The end 180e of the fourth and sixth insulation layers can overlap the metal layer 271 in the thickness direction of the substrate 100. For example, the end 271e of the metal layer can be positioned outside the end 180e of the fourth and sixth insulation layers.

The second wiring 220 can include an end 220e of the second wiring. The end 220e of the second wiring can overlap the metal layer 271 in the thickness direction of the substrate 100. For example, the end 271e of the metal layer can be positioned outside the end 220e of the second wiring.

The functional film 292 can be formed on the fourth insulation layer 181 and the sixth insulation layer 183. The functional film 292 can include the end 292e of the functional film. The end 292e of the functional film can overlap the fourth insulation layer 181 and the sixth insulation layer 183.

The front member 294 can be formed on the functional film 292.

The functional film 292 or the front member 294 can be attached to or combined with the components on the substrate 100. For example, the functional film 292 or the front member 294 can be attached to or combined with the components on the substrate 100 under pressure in the thickness direction of the substrate 100.

Thus, the components disposed between the substrate 100 and the functional film 292 or the front member 294 can receive stress. For example, the first wiring 212, the second wiring 220, or the second insulation layer 123 can receive pressure in the thickness direction of the substrate 100.

In a process in which the functional film 292 and/or the front member 294 are bonded to the components on the substrate 100, the second wiring 220 can be cracked by pressure applied to an upper end of the second wiring 220. For example, the end 220e of the second wiring can be pressured by components formed on an upper end of the second wiring 220, and stress can be concentrated at the end 220e of the second wiring by pressure. For example, corrosion of the second wiring 220 can occur due to the concentrated stress.

Cracks can be generated in the second insulation layer 123 by the end 220e of the second wiring 220 which receives pressure from upper end. The Cracks generated in the second insulation layer 123 can expose the first wiring 212 which is provided at a lower portion of the second insulation layer 123. Accordingly, corrosion can also occur in the first wiring 212.

According to the present disclosure, the end 271e of the metal layer 271 can be located outside the end 220e of the second wiring 220. Accordingly, the stress applied to the end 220e of the second wiring 220 can be reduced, and corrosion of the first wiring 212 and the second wiring 220 can be prevented.

The metal layer 271 can be formed on the third passivation layer 230. For example, the third passivation layer 230 can be formed of an organic material, but is not limited thereto. The third passivation layer 230 can be a planarization layer or an organic layer, but is not limited thereto.

The non-display area 30 can include a first area 31 covering and overlapping the second wiring 220 and a second area 32 adjacent to the first area 31. The metal layer 271 can be formed over the first area 31 and the second area 32 on the third passivation layer 230.

An upper surface of the third passivation layer 230 can be parallel to the substrate 100. For example, the metal layer 271 in contact with the upper surface of the third passivation layer 230 can be parallel to the substrate 100. The distance from the lowermost surface of the substrate 100 to the lowermost surface of the metal layer 271 in the first area 31 and the second area 32 can be the same. For example, the distances between the substrate 100 and the metal layer 271 in the first area 31 and the second area 32 can be the same.

The metal layer 271 can extend from the display area 10 to the outer portion of the end 220e of the second wiring.

A distance from one point of the display area 10 to the end 271e of the metal layer 271 can be greater than a distance from the point of the display area 10 to the end 220e of the second wiring 220.

When a distance from one point of the display area 10 to the end 271e of the metal layer 271 is greater than a distance from the one point of the display area 10 to the end 220e of the second wiring 220, the pressure applied in the thickness direction of the substrate 100 can be dispersed. For example, the stress applied to the end 220e of the second wiring 220 can be reduced as the distance from one point of the display area 10 to the end 271e of the metal layer increases. For example, the stress applied to the second insulation layer 123 can be reduced as the distance from one point of the display area 10 to the end 271e of the metal layer 271 increases. For example, the stress applied to the first wiring 212 can be reduced as the distance from one point of the display area 10 to the end 271e of the metal layer 271e increases. A bank 260 can be formed on the metal layer 271. The bank 260 can be formed of the same material as the third passivation layer 230, but is not limited thereto. The bank 260 can overlap the end 271e of the metal layer. For example, the bank 260 can cover the end 271e of the metal layer, but is not limited thereto.

The fourth insulation layer 181 and the sixth insulation layer 183 can be formed on the metal layer 271. The bank 260 can be formed to be spaced apart from the fourth insulation layer 181 and the sixth insulation layer 183. For example, the end 180e of the fourth insulation layer and the sixth insulation layer can be formed to be spaced apart from the bank 260, but the present disclosure is not limited thereto.

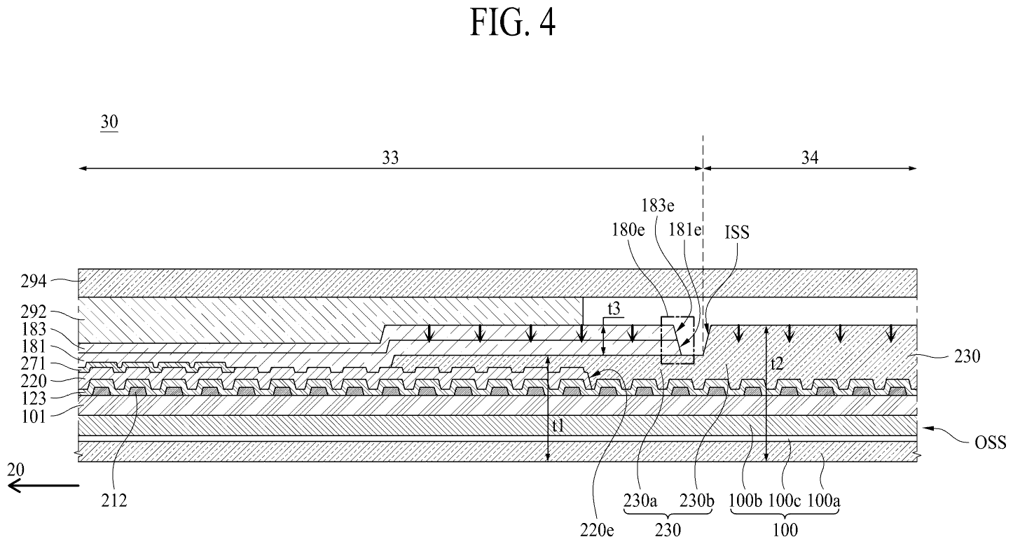

FIG. 4 is a cross-sectional view of a display apparatus according to another embodiment of the present disclosure.

In FIG. 4, description substantially the same as that of FIG. 3 will be omitted, and descriptions different from that of FIG. 3 will be described.

Referring to FIG. 4, the third passivation layer 230 can be formed on the second wiring 220. The fourth insulation layer 181 and the sixth insulation layer 183 can be formed on the third passivation layer 230. The fourth insulation layer 181 and the sixth insulation layer 183 can include the end 180e of the fourth insulation layer and the sixth insulation layer. The functional film 292 can be formed on the fourth insulation layer 181 and the sixth insulation layer 183. The functional film 292 can include the end 292e of the functional film. The end 292e of the functional film can overlap the fourth insulation layer 181 and the sixth insulation layer 183.

The front member 294 can be formed on the functional film 292.

The non-display area 30 can include a third area 33 in which the third passivation layer 230 overlaps the end 180e of the fourth insulation layer and the sixth insulation layer, and a fourth area 34 around the third area 33.

The third passivation layer 230 can include a 3-1th passivation layer 230a in the third area 33 and a 3-2th passivation layer 230b in the fourth area 34. For example, the third passivation layer 230 can be formed over the third area 33 and the fourth area 34 around the third area 33. For example, the 3-1th passivation layer 230a and the 3-2th passivation layer 230b can be portions of the third passivation layer 230.

The 3-1th passivation layer 230a can overlap the end 180e of the fourth and sixth insulation layers. For example, the end 180e of the fourth and sixth insulation layers can be formed in the first area 31. For example, the 3-2th passivation layer 230b can be formed to be spaced apart from the end 180e of the fourth and sixth insulation layers, but is not limited thereto.

The third passivation layer 230 in the third area 33 can be between the second wiring 220 and the fourth insulation layer 181 and the sixth insulation layer 183. For example, the 3-1th passivation layer 230a can be between the second wiring 220 and the fourth insulation layer 181 and the sixth insulation layer 183.

The third passivation layer 230 can have a first thickness t1, which is a distance from the lowermost surface of the substrate 100 to the uppermost surface of the 3-1th passivation layer 230a, and a second thickness t2, which is a distance from the lowermost surface of the substrate 100 to the uppermost surface of the 3-2th passivation layer 230b. For example, the distance t1 from the lowermost surface of the substrate 100 to the uppermost surface of the 3-1th passivation layer 230a can be the thickness of the 3-1th passivation layer 230a, and the distance t2 from the lowermost surface of the substrate 100 to the uppermost surface of the 3-2th passivation layer 230b can be the thickness of the 3-2th passivation layer 230b, but is not limited thereto. For example, the thickness of the 3-1th passivation layer 230a can be the first thickness t1, and the thickness of the 3-2th passivation layer 230b can be the second thickness t2, but is not limited thereto.

The fourth insulation layer 181 and the sixth insulation layer 183 can have a third thickness t3, which is a distance from an uppermost surface of the 3-1th passivation layer 230a to an uppermost surface of the fourth insulation layer 181 or the sixth insulation layer 183. For example, the thickness of the fourth insulation layer 181 and the sixth insulation layer 183 can be a distance from the uppermost surface of the 3-1th passivation layer 230a to the uppermost surface of the fourth insulation layer 181 or the sixth insulation layer 183. For example, the thickness of the fourth insulation layer 181 and the sixth insulation layer 183 can be the third thickness t3.

The first thickness t1 can be different from the second thickness t2. For example, the first thickness t1 can be less than the second thickness t2. The third passivation layer 230 can have different thicknesses through processes such as halftone or etching. For example, a thickness of the third passivation layer 230 in the third area 33 can be different from a thickness of the third passivation layer 230 in the fourth area 34. For example, the thickness of the third passivation layer 230 in the third area 33 can be less than the thickness of the third passivation layer 230 in the fourth area 34. For example, the thickness of the 3-1th passivation layer 230a can be different from the thickness of the 3-2th passivation layer 230b. For example, the thickness of the 3-1th passivation layer 230a can be less than the thickness of the 3-2th passivation layer 230b.

Instead of the third passivation layer 230 having a constant second thickness t2 from the lowermost surface of the substrate 100 to the uppermost surface of the third passivation layer 230, the third passivation layer 230 has the first thickness t1 less than the second thickness t2 and the second thickness t2 from the lowermost surface of the substrate 100 to the uppermost surface of the third passivation layer 230, so that the sum of the second thickness t2 and the third thickness t3 can be less than the sum of the first thickness t1 and the third thickness t3. For example, the second thickness t2 can be equal to the sum of the first thickness t1 and the third thickness t3, but is not limited thereto.

The component on the substrate 100 can be attached to or combined with the functional film 292 and the front member 294 by receiving a force in the thickness direction of the substrate 100. The first wiring 212, the second insulation layer 123, or the second wiring 220 on the substrate 100 can be corroded or cracked by a force when the functional film 292 and the front member 294 are attached to or combined with the component on the substrate 100. For example, the end 220e of the second wiring 220e can be corroded or cracked by a force when the functional film 292 and the front member 294 are attached to or combined with the component on the substrate 100.

The end 220e of the second wiring 220 can receive less force as the sum of the first thickness t1 and the third thickness t3 is equal to the second thickness t2. For example, as the sum of the first thickness t1 and the third thickness t3 is equal to the second thickness t2, the pressure applied to the component on the substrate 100 can be dispersed. For example, when the functional film 292 and the front member 294 are attached to or combined with the substrate 100, the first wiring 212 and the second wiring 220 can receive less pressure.

Referring to FIG. 4, the metal layer 271 is in contact with both the second wiring 220 and the fourth insulation layer 181. Here, the metal layer 271 is spaced apart from the third passivation layer 230.

The fourth insulation layer 181 includes an end 181e and the sixth insulation layer 183 includes an end 183e, which collectively can be referred to as an end 180e. In some embodiments, the end 180e of the insulation layer 181 or 183 is located closer to an outermost side surface OSS of the display apparatus (or the substrate 100) than the end 220e of the second wiring 220.

In some embodiments, the end 181e of the fourth insulation layer 181 or the end 183e of the sixth insulation layer 183 is spaced apart from the inclined side surface ISS of the third passivation layer 230.

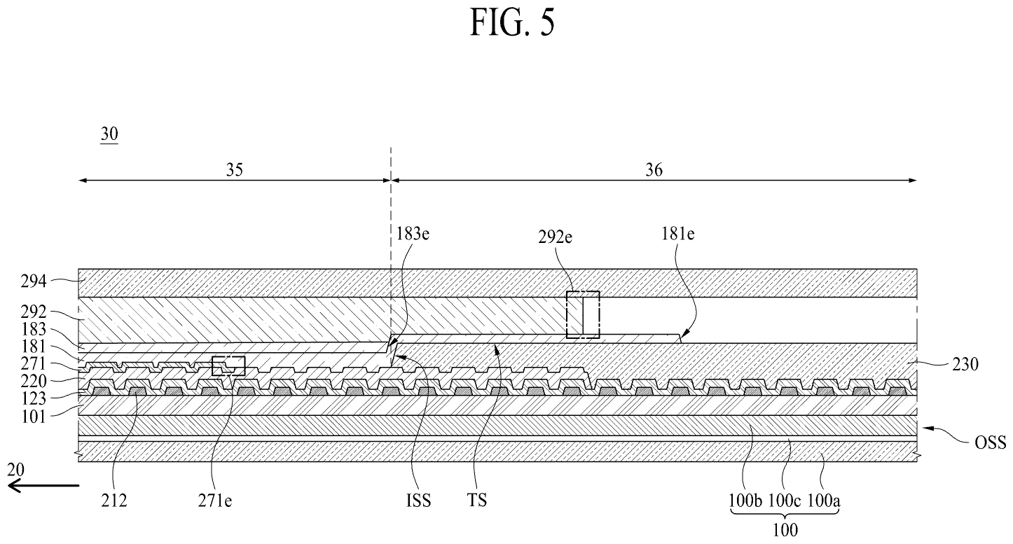

FIG. 5 is a cross-sectional view of a display apparatus according to another embodiment of the present disclosure.

In FIG. 5, description substantially the same as that of FIG. 3 will be omitted, and descriptions different from that of FIG. 3 will be described.

Referring to FIG. 5, a fourth insulation layer 181 can be formed on the second wiring 220. A sixth insulation layer 183 can be formed on the fourth insulation layer 181. The fourth insulation layer 181 can include an end 181e of the fourth insulation layer. The sixth insulation layer 183 can include an end 183e of the sixth insulation layer. The non-display area 30 can include a fifth area 35 in which the third passivation layer 230 overlaps at least one of the end 181e of the fourth insulation layer and the end 183e of the sixth insulation layer, and a sixth area 36 around the fifth area 35.

A metal layer 271 can be formed on the second wiring 220. The second wiring 220 can be between the metal layer 271 and the fourth insulation layer 181.

The end 181e of the fourth insulation layer and the end 183e of the sixth insulation layer can be formed to be spaced apart from each other. For example, the end 183e of the sixth insulation layer can overlap the fourth insulation layer 181. For example, the fourth insulation layer 181 can extend to the sixth area 36 through the fifth area 35. For example, the end 220e of the second wiring can overlap the fourth insulation layer 181. For example, the end 220e of the second wiring can overlap at least one insulation layer. For example, the end 183e of the sixth insulation layer can be between the display area 20 and the third passivation layer 230.

The fourth insulation layer 181 can be a lower insulation layer, and the sixth insulation layer 183 can be an upper insulation layer, but is not limited thereto. The end 181e of the fourth insulation layer can be an end of the lower insulation layer, and the end 183e of the sixth insulation layer can be an end of the upper insulation layer, but is not limited thereto.

In the display apparatus according to an embodiment of the present disclosure, the sixth insulation layer 183 can extend from the fifth area 35 to the sixth area 36.

A functional film 292 can be formed on the fourth and sixth insulation layers 181 and 183. The functional film 292 can include the end 292e of the functional film. The end 292e of the functional film can overlap the fourth and sixth insulation layers 181 and 183.

A front member 294 can be formed on the functional film 292.

In the display apparatus according to an embodiment of the present disclosure, when the functional film 292 and the front member 294 are attached to or combined with the substrate 100, the first wiring 212 and the second wiring 220 can receive less pressure. For example, when the functional film 292 and the front member 294 are attached to or combined with the substrate 100, the first wiring 212 and the second wiring 220 can receive less pressure.

Referring to FIG. 5, the metal layer 271 is in contact with both the second wiring 220 and the fourth insulation layer 181. Here, the metal layer 271 is spaced apart from the third passivation layer 230.

The end 183e of the sixth insulation layer 183 is spaced apart from the third passivation layer 230. In some embodiments, the end 181e of the fourth insulation layer 181 is closer to an outermost side surface OSS of the display apparatus (or the substrate 100) than the end 183e of the sixth insulation layer 183.

As shown, the fourth insulation layer 181 extends to the inclined side surface ISS and the top surface TS of the third passivation layer 230. Here, the fourth insulation layer 181 covers and is in direct contact with the inclined side surface ISS and the top surface TS of the third passivation layer 230.

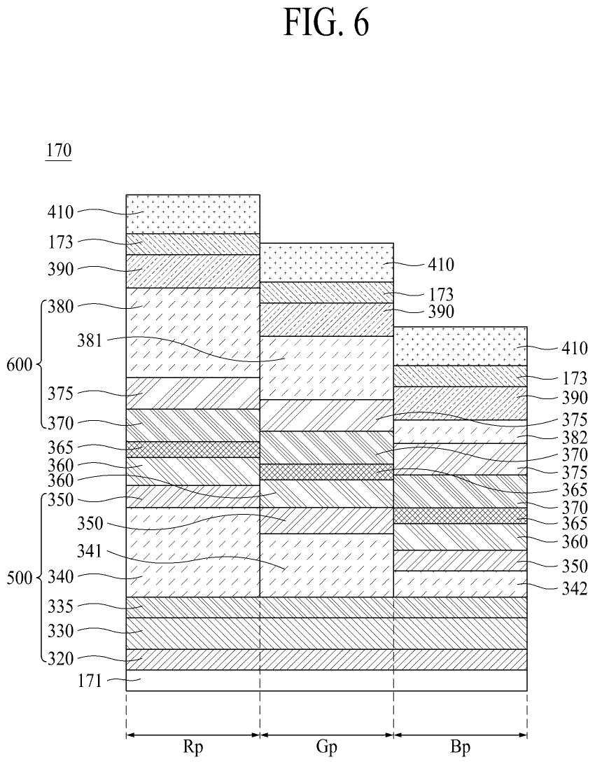

FIG. 6 is a cross-sectional view of an element of a display apparatus according to embodiments of the present disclosure.

Referring to FIG. 6, the display apparatus can include a light emitting unit 170.

The light emitting unit 170 includes a first electrode 171 formed on a substrate having a red subpixel area Rp, a green subpixel area Gp, and a blue subpixel area Bp defined therein, a hole injection layer 320 (HIL), a first hole transporting layer 330 (1st HTL), a first hole control layer 335 (1st HCL), a first organic emission layer including a first red emission layer 340 (1st Red EML), a first green emission layer 341 (1st Green EML), and a first blue emission layer 342 (1st Blue EML), a first electron transporting layer 350 (1st ETL), a first charge generation layer 360 (N-CGL), a second charge generation layer 365 (P-CGL), a second hole transporting layer 370 (2nd HTL), a second hole control layer 375 (2nd HCL), a second organic emission layer including a second red emission layer 380 (2nd Red EML), a second green emission layer 381 (2nd Green EML), and a second blue emission layer 382 (2nd Blue EML), a second electron transporting layer 390 (2nd ETL), a second electrode 173 (cathode), and a capping layer 410.

Moreover, the light emitting unit 170 according to an embodiment of the present disclosure can be an organic light emitting device having a two-stack structure in which a first light emitting unit 500 (1st EL Unit) including the first organic emission layer and a second light emitting unit 600 (2nd EL Unit) including the second organic emission layer are stacked between the first electrode 171 and the second electrode 173.

For example, in the light emitting unit 170 according to an embodiment of the present disclosure, the first light emitting unit 500 is configured to include the hole injection layer 320, the first hole transporting layer 330, the first hole control layer 335, the first organic emission layer including the first red emission layer 340, the first green emission layer 341, and the first blue emission layer 342, and the first electron transporting layer 350.

In the light emitting unit 170 according to an embodiment of the present disclosure, the second light emitting unit 600 can include the second hole transporting layer 370, the second hole control layer 375, the second organic emission layer including the second red emission layer 380, the second green emission layer 381, and the second blue emission layer 382, and the second electron transporting layer 390.

The light emitting unit 170 according to an embodiment of the present disclosure can include the first charge generation layer 360, which is an n-type charge generation layer, and a second charge generation layer 365, which is a p-type charge generation layer. The first charge generation layer 360 and the second charge generation layer 365 are provided between the first light emitting unit 500 and the second light emitting unit 600.

In a display apparatus including the light emitting unit according to an embodiment of the present disclosure, a gate line and a data line intersecting each other to define each pixel area and a power line extending parallel to any one of the gate line and the data line are provided on the substrate. Also, a switching thin film transistor connected to the gate line and the data line and a driving thin film transistor connected to the switching thin film transistor can be provided in each pixel area. The driving thin film transistor can be connected to the first electrode 171.

The first electrode 171 is provided on the substrate to correspond to each of the red subpixel area Rp, the green subpixel area Gp, and the blue subpixel area Bp, and can be formed of a reflective electrode.

For example, the first electrode 171 can include a transparent conductive material layer having a high work function such as indium-tin-oxide (ITO) and a reflective material layer such as silver (Ag) or an Ag alloy, but embodiments of the present disclosure are not limited thereto.

The hole injection layer 320 can be provided on the first electrode 171 to correspond to all of the red subpixel area Rp, the green subpixel area Gp, and the blue subpixel area Bp.

The hole injection layer 320 can facilitate hole injection, and can be formed of at least one of HATCN (1,4,5,8,9,11-hexaazatryphenylene-hexanitrile), CuPc (cup phthalocyanine), PEDOT (poly(3,4)-ethylenedioxythiophene), PANI (polyaniline), and NPD (N,N-dinaphthyl-N,N′-diphenylbenzidine), but is not limited thereto.

Each of the first hole transporting layer 330 and the second hole transporting layer 370 is formed to correspond to all of the red subpixel area Rp, the green subpixel area Gp, and the blue subpixel area Bp. The first hole transporting layer 330 can be located on the hole injection layer 320 and the second hole transporting layer 370 can be located on the second charge generation layer 365.

The first hole transporting layer 330 and the second hole transporting layer 370 can facilitate a transport of holes, and can be formed of at least one of NPD (N,N-dinaphthyl-N,N′-diphenylbenzidine), TPD (N,N′-bis-(3-methylphenyl)-N,N′-bis-(phenyl)-benzidine), s-TAD and MTDATA (4,4′,4″-Tris(N-3-methylphenyl-N-phenyl-amino)-triphenylamine), but is not limited thereto.

In the light emitting unit 170 according to an embodiment of the present disclosure, the first hole control layer 335 can be positioned on the first hole transporting layer 330 to correspond to all of the red subpixel area Rp, the green subpixel area Gp, and the blue subpixel area Bp.

The second hole control layer 375 can be positioned on the second hole transporting layer 370 to correspond to all of the red subpixel area Rp, the green subpixel area Gp, and the blue subpixel area Bp.

Because the first hole control layer 335 and the second hole control layer 375 have a higher mobility characteristic of holes than electrons at a high temperature, it is possible to prevent a phenomenon in which holes move through the first organic emission layer and the second organic emission layer to the first electron transporting layer 350 and the second electron transport layer 390 to leave the light emitting area. The first organic emission layer includes the first red emission layer 340, the first green emission layer 341, and the first blue emission layer 342 which are regions in which electrons and holes recombine to emit light and the second organic light emission layer including the second red emission layer 380, the second green emission layer 381, and the second blue emission layer 382. The first hole control layer 335 and the second hole control layer 375 can be formed of a material such as a carbazole derivative, a triarylamine derivative, a triamine derivative, or the like. For example, the first hole control layer 335 and the second hole control layer 375 can be formed of at least one of TPD (N,N′-Bis(3-methylphenyl)-N,N′-bis(phenyl)-benzidine), α-NPB (Bis [N-(1-naphthyl)-N-phenyl]benzidine), TDAPB (1,3,5-tris(4-diphenylaminophenyl)benzene), TCTA (Tris(4-carbazoyl-9-yl)triphenylamine), spiro-TAD (2,2′,7,7′-Tetrakis(N,N-diphenylamino)-9,9-spirobifluorene), CBP (4,4′-bis(carbazol-9-yl) biphenyl), BFA-1T (4-[bis(9,9-dimethylfluoren-2-yl)amino]phenyl group), spiro-TCBz (triclabendazole) and TBA, but the present disclosure is not limited thereto.

The first hole control layer 335 and the second hole control layer 375 can be formed of the same material among the above-described materials, and can be formed of different materials among the above-described materials in consideration of mobility characteristics of holes in the first light emitting unit 500 and the second light emitting unit 600.

The first red emission layer 340 can be located in the red subpixel area Rp on the first hole transporting layer 330, and the second red emission layer 380 can be located in the red subpixel area Rp on the second hole transporting layer 370. Each of the first red emission layer 340 and the second red emission layer 380 can include a light emitting material emitting red light, and the light emitting material can be formed using a phosphorescent material or a fluorescent material.

For example, the first red emission layer 340 and the second red emission layer 380 can include a host material including CBP (4,4′-bis(carbozol-9-yl) biphenyl) or mCP (1,3-bis(N-carbozol)benzene), can include a phosphorescent material including a dopant which includes at least one a PQIr (acac) (bis(1-phenylquinoline) acetylacetonate iridium), PQIr (tris(1-phenylquinoline) iridium), and PtOEP (octaethylpropyrrin platinum), and on the other hand, can be formed of a fluorescent material including PBD:Eu (DBM)3(Phen)) or Perylene, but are not limited thereto.

The first green emission layer 341 can be located in the green subpixel area Gp on the first hole transporting layer 330, and the second green emission layer 381 can be located in the green subpixel area Gp on the second hole transporting layer 370. Each of the first green emission layer 341 and the second green emission layer 381 can include a light emitting material emitting green light, and the light emitting material can be formed using a phosphorescent material or a fluorescent material.

For example, the first green emission layer 341 and the second green emission layer 381 can include a host material including CBP or mCP, can be formed of a phosphorescent material including a dopant material such as an iridium complex containing Ir(ppy)3 (fac tris(2-phenylpyridine) iridium), and on the other hand, can be formed of a fluorescent material including Alq3 (tris(8-hydroxyquinolino) aluminum), but is not limited thereto.

The first blue emission layer 342 can be located in the blue subpixel area Bp on the first hole transporting layer 330, and the second blue emission layer 382 can be located in the blue subpixel area Bp on the second hole transporting layer 370. Each of the first blue emission layer 342 and the second blue emission layer 382 can include a light emitting material emitting blue light, and the light emitting material can be formed using a phosphorescent material or a fluorescent material.

For example, the first blue emission layer 342 and the second blue emission layer 382 can include a host material including CBP or mCP, and can include a phosphorescent material including a dopant material including (4,6-F2ppy) 2Irpic, but embodiments of the present disclosure are not limited thereto. Also, the first blue emission layer 342 and the second blue emission layer 382 can be formed of a fluorescent material including any one of spiro-DPVBi, spiro-6P, distylbenzene (DSB), dystrylarylene (DSA), a PFO-based polymer, and a PPV-based polymer, but is not limited thereto.

The first electron transporting layer 350 can be located on the first red emission layer 340, the first green emission layer 341, and the first blue emission layer 342 to correspond to all of the red subpixel area Rp, the green subpixel area Gp, and the blue subpixel area Bp, and the second electron transporting layer 390 can be located on the second red emission layer 380, the second green emission layer 381, and the second blue emission layer 382 to correspond to all of the red subpixel area Rp, the green subpixel area Gp, and the blue subpixel area Bp.

The first electron transporting layer 350 and the second electron transporting layer 390 can transport and inject electrons, and the thicknesses of the first electron transporting layer 350 and the second electron transporting layer 390 can be adjusted in consideration of electron transport characteristics.

The first electron transporting layer 350 and the second electron transporting layer 390 facilitate the transport of electrons, and can be formed of at least one of Alq3 (tris(8-hydroxyquinolino) aluminum), PBD (2-(4-biphenylyl)-5-(4-tert-butylpheny)-1,3,4oxadiazole), TAZ, spiro-PBD, BAlq, and SAlq, but are not limited thereto.

It is possible to separately provide an electron injection layer (EIL) on the second electron transporting layer 390.

The electron injection layer (EIL) can be formed of Alq3 (tris(8-hydroxyquinolino) aluminum), PBD (2-(4-biphenylyl)-5-(4-tert-butylpheny)-1,3,4oxadiazole), TAZ, spiro-PBD, BAlq, or SRq, but is not limited thereto.

Here, the structure thereof is not limited according to an embodiment of the present disclosure, and at least one of the hole injection layer 320, the first hole transporting layer 330, the second hole transporting layer 370, the first electron transporting layer 350, the second electron transporting layer 390, and the electron injection layer EIL can be omitted. Also, at least one of the first hole transporting layer 330, the second hole transporting layer 370, the first electron transporting layer 350, the second electron transporting layer 390, and the electron injection layer EIL can be formed in two or more layers.

The first charge generation layer 360 can be located on the first electron transporting layer 350 to correspond to all of the red subpixel area Rp, the green subpixel area Gp, and the blue subpixel area Bp, the second charge generation layer 365 can be located on the first charge generation layer 360 to correspond to all of the red subpixel area Rp, the green subpixel area Gp, and the blue subpixel area Bp, and the first charge generation layer 360 and the second charge generation layer 365 can have an NP junction structure.

Referring to FIG. 7, the first charge generation layer 360 and the second charge generation layer 365 are provided between the first light emitting unit 500 and the second light emitting unit 600, and the first charge generation layer 360 and the second charge generation layer 365 can adjust the charge balance between the first light emitting unit 500 and the second light emitting unit 600.

The first charge generation layer 360 can perform the function as an n-type charge generation layer (n-CGL) which helps injection of electrons to the first light emitting unit 500 located below the first charge generation layer 360, and the second charge generation layer 365 can perform the function as a p-type charge generation layer (p-CGL) which helps injection of holes to the second light emitting unit 600 located above the second charge generation layer 365.

For example, the first charge generation layer 360, which is an n-type charge generation layer (n-CGL) performing a function as an electron injection, can be formed of an alkali metal, an alkali metal compound, an organic material serving as an electron injection, or a compound thereof. Also, the host material of the first charge generation layer 360 can be formed of the same material as that of the first electron transporting layer 350 and the second electron transporting layer 390. For example, the host material of the first charge generation layer 360 can be formed of a mixed layer in which an organic material such as an anthracene derivative is doped with a dopant such as lithium (Li), but is not limited thereto.

The second charge generation layer 365 is provided on the first charge generation layer 360. The second charge generation layer 365 can perform the function as a p-type charge generation layer (p-CGL) serving as a hole injection, and the host material of the second charge generation layer 365 can be formed of the same material as the material of the first hole injection layer 320, the first hole transporting layer 330, and the second hole transporting layer 370. For example, the second charge generation layer 365 can be formed of a mixed layer in which an organic material such as a HATCN (1,4,5,8,9,11-hexaazatryphenylene-hexanitrile), CuPc (cupper phthalocyanine), and TBAHA (tris(4-bromophenyl) aluminum hexachlorantimonate) is doped with a p-type dopant, but is not limited thereto. Moreover, the p-type dopant can be formed of either F4-TCNQ or NDP-9, but is not limited thereto.

The second electrode 173 is provided on the second electron transporting layer 390 to correspond to all of the red subpixel area Rp, the green subpixel area Gp, and the blue subpixel area Bp. For example, the second electrode 173 can be formed of an alloy of magnesium and silver (Mg:Ag) and can have semi-transmissive characteristics. For example, the light emitted from the organic emission layer can be displayed to the outside through the second electrode 173, and because the second electrode 173 has the semi-transmissive characteristic, some of the light can be directed to the first electrode 171 again.

As such, light is repeatedly reflected in the cavity between the first electrode 171 and the second electrode 173 due to the micro cavity effect in which repeated reflection occurs between the second electrode 173 and the first electrode 171 acting as a reflective layer, thereby increasing light efficiency.

In addition, it is also possible to form the first electrode 171 as a transmissive electrode and the second electrode 173 as a reflective electrode so that light from the organic emission layer is displayed to the outside through the first electrode 171.

The capping layer 410 is provided on the second electrode 173. The capping layer 410 can increase a light extraction effect in the light emitting portion. The capping layer 410 can be formed of any one of the first hole transporting layer 330, the second hole transporting layer material, the first electron transporting layer 350, the second electron transporting layer material, and the host material of the first red emission layer 340, the second red emission layer 380, the first green emission layer 341, the second green emission layer 381, the first blue emission layer 342, and the second blue emission layer 382, but embodiments of the present disclosure are not limited thereto. Also, the capping layer 410 can be omitted.

A display apparatus according to embodiments of the present disclosure can be described as follows.

A display apparatus according to embodiments of the present disclosure comprises a substrate including a display area and a non-display area around the display area, pixels in the display area, a wiring electrically connected to pixels and extending from the display area to the non-display area, a passivation layer covering an end of the wiring in the non-display area, and an insulation layer on the passivation layer in a thickness direction of the substrate and overlapping the end of the wiring, wherein the passivation layer and the insulation layer provided in the thickness direction of the substrate overlap each other at an end of the wiring.

According to embodiments of the present disclosure, the display apparatus further comprises a metal layer on the wiring.

According to embodiments of the present disclosure, a portion of the metal layer contact the wiring, and the rest of the metal layer contact the passivation layer.

According to embodiments of the present disclosure, the passivation layer covers the wiring and includes a first area overlapping the wiring and a second area around the first area, and the metal layer is formed over the first area and the second area on the passivation layer.

According to embodiments of the present disclosure, distances between the substrate and the metal layer in the first area and the second area are the same.

According to embodiments of the present disclosure, the display apparatus further comprises a bank on the passivation layer, wherein the bank covers an end of the metal layer.

According to embodiments of the present disclosure, the bank is spaced apart from the insulation layer.

According to embodiments of the present disclosure, the metal layer overlaps an end of the insulation layer.

According to embodiments of the present disclosure, the passivation layer includes a third area overlapping an end of the insulation layer and a fourth area around the third area, and a thickness of the passivation layer in the third area and a thickness of the passivation layer in the fourth area are different.

According to embodiments of the present disclosure, the passivation layer in the fourth area is provided between the wiring and the insulation layer.

According to embodiments of the present disclosure, the thickness of the passivation layer in the third area is less than the thickness of the passivation layer in the fourth area.

According to embodiments of the present disclosure, the insulation layer comprises a lower insulation layer on the wiring and an upper insulation layer on the lower insulation layer.

According to embodiments of the present disclosure, the passivation layer includes a fifth area overlapping at least one end of the insulation layers and a sixth area around the fifth area, and the lower insulation layer extends from the fifth area to the sixth area.

According to embodiments of the present disclosure, an end of the upper insulation layer is provided between the display area and the passivation layer.

According to embodiments of the present disclosure, the display apparatus further comprises a metal layer on the wiring, wherein the wiring is provided between the metal layer and the lower insulation layer.

According to embodiments of the present disclosure, the display apparatus further comprises a functional film on the insulation layer.

According to embodiments of the present disclosure, an end of the functional film overlaps the insulation layer.

According to embodiments of the present disclosure, the display apparatus further comprises a front member on the functional film.

According to embodiments of the present disclosure, the display apparatus further comprises a thin film transistor on the substrate, wherein the thin film transistor includes a gate electrode and a source electrode and a drain electrode on the gate electrode, and the wiring is provided on the same layer as the source electrode and the drain electrode.

According to embodiments of the present disclosure, a display apparatus capable of preventing corrosion of wiring can be provided.

According to embodiments of the present disclosure, a display apparatus having a structure in which a pressure applied to a wiring can be reduced can be provided. Accordingly, corrosion of a wiring can be prevented.

The effects of the present disclosure are not limited to those mentioned above, and another effect not mentioned will be clearly understood by those skilled in the art.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area and a non-display area around the display area;
pixels in the display area;
a wiring electrically connected to pixels and extending from the display area to the non-display area;
a passivation layer covering an end of the wiring in the non-display area; and
an insulation layer on the passivation layer in a thickness direction of the substrate and overlapping the end of the wiring,
wherein the passivation layer and the insulation layer provided in the thickness direction of the substrate overlap each other at an end of the wiring.

2. The display apparatus of claim 1, further comprising a metal layer on the wiring.

3. The display apparatus of claim 2, wherein a portion of the metal layer contact the wiring, and the rest of the metal layer contact the passivation layer.

4. The display apparatus of claim 2, wherein the passivation layer covers the wiring and includes a first area overlapping the wiring and a second area around the first area, and
wherein the metal layer is formed over the first area and the second area on the passivation layer.

5. The display apparatus of claim 4, wherein distances between the substrate and the metal layer in the first area and the second area are the same.

6. The display apparatus of claim 4, further comprising a bank on the passivation layer,
wherein the metal layer includes an end, and
wherein the bank covers the end of the metal layer.

7. The display apparatus of claim 6, wherein the bank is spaced apart from the insulation layer.

8. The display apparatus of claim 4, wherein the metal layer overlaps an end of the insulation layer.

9. The display apparatus of claim 1, wherein the passivation layer includes a third area overlapping an end of the insulation layer and a fourth area around the third area, and
wherein a thickness of the passivation layer in the third area and a thickness of the passivation layer in the fourth area are different.

10. The display apparatus of claim 9, wherein the passivation layer in the fourth area is provided between the wiring and the insulation layer.

11. The display apparatus of claim 9, wherein the thickness of the passivation layer in the third area is less than the thickness of the passivation layer in the fourth area.

12. The display apparatus of claim 1, wherein the insulation layer comprises:
a lower insulation layer on the wiring; and
an upper insulation layer on the lower insulation layer.

13. The display apparatus of claim 12, wherein the passivation layer includes a fifth area overlapping at least one end of the insulation layers and a sixth area around the fifth area, and
wherein the lower insulation layer extends from the fifth area to the sixth area.

14. The display apparatus of claim 13, wherein an end of the upper insulation layer is provided between the display area and the passivation layer.

15. The display apparatus of claim 13, further comprising a metal layer on the wiring,
wherein the wiring is provided between the metal layer and the lower insulation layer.

16. The display apparatus of claim 1, further comprising a functional film on the insulation layer.

17. The display apparatus of claim 16, wherein an end of the functional film overlaps the insulation layer from a plan view.

18. The display apparatus of claim 16, further comprising a front member on the functional film.

19. The display apparatus of claim 1, further comprising a thin film transistor on the substrate,
wherein the thin film transistor includes a gate electrode and a source electrode and a drain electrode on the gate electrode, and
wherein the wiring is provided on a same layer as the source electrode and the drain electrode.

20. A display apparatus comprising:
a substrate including a display area and a non-display area adjacent to the display area;
a plurality of pixels in the display area;
a plurality of wirings electrically connected to the plurality of pixels, the plurality of wirings including a first wiring and a second wiring on the first wiring, the second wiring having a first end;
a passivation layer covering the first end of the second wiring in the non-display area; and
an insulation layer on the passivation layer, the insulation layer overlapping the first end of the second wiring from a plan view,
wherein the first end of the second wiring is located at an area where both the passivation layer and the insulation layer overlap with each other from a plan view.
